(19) United States
(12) Patent Application Publication
(10) Pub. No.: US 2019/0126427 A1
(43) Pub. Date: May 2, 2019

(54) SUBSTRATE PROCESSING APPARATUS

(71) Applicant: Ebara Corporation, Tokyo (JP)

(72) Inventors: Yoshikazu Kato, Tokyo (JP); Makoto Fukushima, Tokyo (JP)

(21) Appl. No.: 16/171,505

(22) Filed: Oct. 26, 2018

(30) Foreign Application Priority Data
Oct. 31, 2017 (JP) 2017-209864

(51) Int. Cl. B24B 37/013; B24B 37/10; B24B 37/20; H01L 21/306; H01L 21/66

(52) U.S. Cl. CPC B24B 37/013; B24B 37/105; H01L 22/26; H01L 21/30625; B24B 37/20

(57) ABSTRACT

A substrate processing apparatus includes a substrate polishing unit that includes a polishing pad and a top ring that holds and presses a wafer against the polishing pad. The top ring includes an annular retainer ring that supports the outer periphery of the wafer, a deflection detector that detects a pressing force with which the wafer presses the retainer ring, and a controller that determines that a polishing processing on the wafer has ended when the amount of change in the pressing force exceeds a predetermined value. The deflection detector includes a pressing target that undergoes deflection by being pressed by the wafer during a polishing process, a pressure detector that detects an amount of deflection of the pressing target as the pressing force, and a support that supports the pressing target and the pressure detector.

### CROSS-REFERENCE TO RELATED APPLICATIONS

This application is based on and claims priority from Japanese Patent Application No. 2017-209864, filed on Oct. 31, 2017, with the Japan Patent Office, the disclosure of which is incorporated herein in their entireties by reference.

### TECHNICAL FIELD

The present disclosure relates to a substrate processing apparatus that processes the surface of a substrate such as, for example, a semiconductor wafer.

### BACKGROUND

In the process of manufacturing semiconductor devices, polishing apparatuses have been widely used to polish the surface of a wafer. In this type of polishing apparatus, the wafers are rotated while being held by a substrate holding device called a top ring or a polishing head. In this state, while rotating a polishing table together with a polishing pad, the surface of the wafer is pressed against a polishing surface of the polishing pad, and the surface of the wafer is brought into a sliding contact with the polishing surface under the presence of a polishing liquid, thereby polishing the surface of the wafer.

Since a frictional force acts on the wafer during the polishing, it is necessary to hold the wafer in order to prevent the wafer from being separated from the substrate holding device during the polishing. Therefore, in the substrate holding device, a retainer ring formed with a ring-shape is provided so as to surround the outer periphery of the wafer held by the substrate holding device. The retainer ring comes at the lower end surface thereof into contact with the polishing pad to receive the wafer at the inner peripheral surface thereof during the polishing, thereby preventing the wafer from protruding.

In order to prevent the wafer from slipping out of the top ring during the polishing, Japanese Patent Laid-Open Publication No. 11-000860 discloses a wafer polishing apparatus in which a pressure sensor is disposed outside a retainer ring. The pressure sensor detects a pressing force generated when the wafer presses the inner peripheral surface of the retainer ring during the polishing, and determines a state where the wafer slides out when the detected amount of decrease in pressure reaches the reference value.

In addition, in the polishing apparatus described in Japanese Patent Laid-Open Publication No. 11-000860, a contact area between a polishing target surface of the wafer and the polishing pad increases as polishing proceeds, so that a frictional resistance acting on the wafer increases and a pressure acting on the retainer ring in a radially outward direction gradually increases. Therefore, the end point of polishing is detected from a change in the pressure detected by the pressure sensor.

### SUMMARY

According to an aspect of the present disclosure, there is provided a substrate processing apparatus including a retainer ring having an annular shape configured to support an outer periphery of a substrate to be polished; and a first sensor provided inside the retainer ring and configured to detect a pressing force with which the substrate presses the retainer ring during a polishing process of the substrate. With this configuration, the pressing force pressing the retainer ring may be directly detected due to a frictional force between the substrate and a polishing member. Therefore, it is possible to more accurately detect the timing of the end of polishing by detecting a change in the pressing force depending on a change in the frictional force

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a plan view schematically illustrating a configuration of a substrate processing apparatus according to an embodiment of the present disclosure.

FIG. 2 is a perspective view schematically illustrating an embodiment of a substrate polishing unit.

FIG. 3 is a side view illustrating an outline of a configuration of the substrate polishing unit.

FIG. 4 is a side view partially illustrating the configuration of the substrate polishing unit.

FIG. 5 is a view schematically illustrating a structure of a deflection detection device.

FIG. 6 is an explanatory view illustrating an exemplary temporal transition of a pressure value detected by the deflection detection device.

FIG. 7 is an explanatory view illustrating an arrangement of the deflection detection device.

FIG. 8 is an explanatory view illustrating a state where a wafer that is being polished presses a retainer ring.

FIG. 9 is an explanatory view illustrating another example of the deflection detection device.

FIG. 10 is an explanatory view illustrating another example of the structure of the deflection detection device.

FIG. 11 is an explanatory view illustrating another example of the structure of the deflection detection device.

FIG. 12 is an explanatory view illustrating another example of the structure of the deflection detection device.

FIG. 13 is an explanatory view illustrating another example of the arrangement of the deflection detection device.

### DESCRIPTION OF EMBODIMENT

In the following detailed description, reference is made to the accompanying drawings, which form a part hereof. The illustrative embodiments described in the detailed description, drawings, and claims are not meant to be limiting. Other embodiments may be utilized, and other changes may be made, without departing from the spirit or scope of the subject matter presented here.

Along with higher integration and higher density of semiconductor devices, the wiring of circuits has become finer and the number of layers of a multilayer wiring has also increased. Therefore, it is important to more accurately detect the timing of the end of a substrate polishing processing. In the polishing apparatus described in the above patent document, the pressing force transmitted through the retainer ring from the wafer is detected by the pressure sensor provided outside the retainer ring. However, the pressing force received by the retainer ring receives from the wafer changes according to polishing conditions and the retainer ring itself wears due to polishing and the amount of deflection thereof also fluctuates. Thus, the configuration of the related art has difficulty in accurately detecting a change in the pressing force from the wafer.

The present disclosure has been made in consideration of the above circumstance, and an object of the present disclosure is to provide a substrate processing apparatus capable of more accurately detecting the end of polishing of a wafer by more accurately detecting a pressing force from the wafer that is being polished.

According to an aspect of the present disclosure, there is provided a substrate processing apparatus including a retainer ring having an annular shape configured to support an outer periphery of a substrate to be polished; and a first sensor provided inside the retainer ring and configured to detect a pressing force with which the substrate presses the retainer ring during a polishing process of the substrate. With this configuration, the pressing force pressing the retainer ring may be directly detected due to a frictional force between the substrate and a polishing member. Therefore, it is possible to more accurately detect the timing of the end of polishing by detecting a change in the pressing force depending on a change in the frictional force.

According to another aspect of the present disclosure, there is provided a substrate processing apparatus including a retainer ring having an annular shape configured to support an outer periphery of a substrate to be polished; a first sensor provided inside the retainer ring and configured to detect a pressing force with which the substrate presses the retainer ring during a polishing process of the substrate; and a controller configured to determine that the polishing process performed on the substrate has ended when an amount of change in a pressing force detected by the first sensor deviates from a predetermined range. With this configuration, the pressing force pressing the retainer ring may also be directly detected due to a frictional force between the substrate and a polishing member. Therefore, it is possible to more accurately detect the timing of the end of polishing end by detecting a change in the pressing force due to a change in the frictional force.

In the substrate processing apparatus according to the present disclosure, the first sensor may be a deflection detector including a pressing target that undergoes a deflection by being pressed by the substrate during the polishing process; a pressure detector disposed adjacent to the pressing target and configured to detect an amount of deflection of the pressing target as the pressing force; and a support configured to support the pressing target and the pressure detector.

In the substrate processing apparatus according to the present disclosure, one end of the pressing target may not be supported by the support. In addition, the pressing target and the pressure detector may be embedded in the support. Alternatively, the pressure detector may be embedded in the support member, and the pressing target may be attached to an outer surface of the support. Moreover, a pressure transmitter may be disposed between the pressing target and the pressure detector to transmit the pressing force that the pressing target portion has received from the substrate to the pressure detector.

In the substrate processing apparatus according to the present disclosure, a plurality of deflection detectors may be disposed at a plurality of positions in the retainer ring, and the controller may determine the end of polishing based on information on the pressing force from the plurality of deflection detectors. With this configuration, it is possible to accurately detect the timing of end of polishing even when an uneven pressing force is applied to the retainer ring by the substrate due to a gap between the retainer ring and the substrate.

The substrate processing apparatus may further include a second sensor provided in a vicinity of the first sensor inside the retainer ring and configured to detect a pressing force from a polishing pad that polishes the substrate, and the controller may determine whether or not to replace the retainer ring based on an amount of change in the pressing force detected from the second sensor. With this configuration, it is possible to accurately detect the timing of replacement of the retainer ring that is an expendable item.

According to the present disclosure, due to the fact that the first sensor that detects the pressing force generated when the substrate that is being polished presses the retainer ring is provided inside the retainer ring, it is possible to directly detect the pressing force pressing the retainer ring due to the frictional force between the substrate and the polishing member, and to more accurately detect the timing of the end of polishing by detecting a change in the pressing force depending on a change in the frictional force.

Hereinafter, a substrate processing apparatus according to an embodiment of the present disclosure will be described with reference to the accompanying drawings. In addition, the same or corresponding constituent elements will be denoted by the same reference numerals, and a redundant description thereof will be omitted.

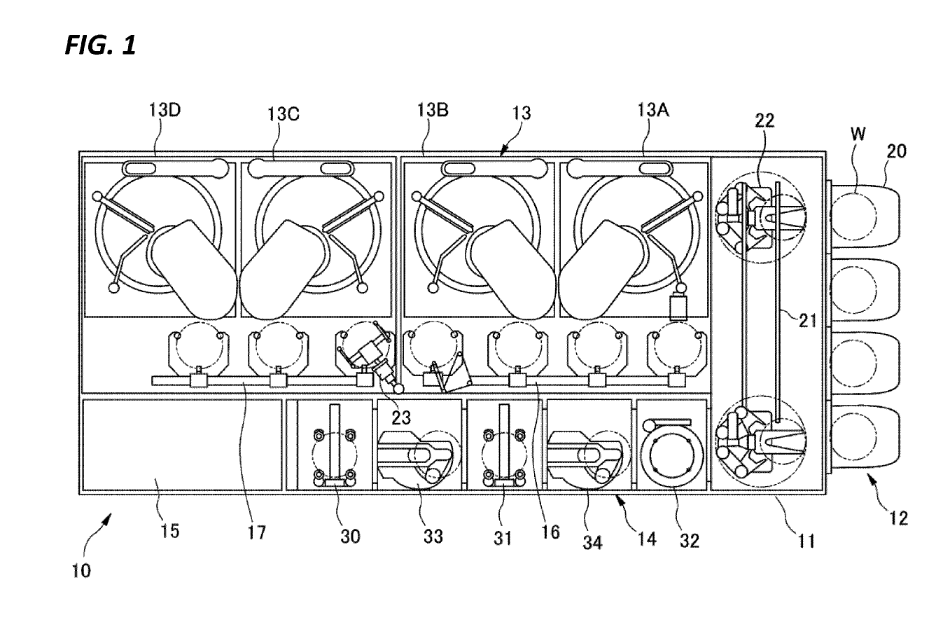

FIG. 1 is a plan view illustrating an overall configuration of a substrate processing apparatus. The substrate processing apparatus 10 is partitioned into a loading/unloading section 12, a polishing section 13, and a cleaning section 14, and these sections are provided inside a rectangular housing 11. In addition, the substrate processing apparatus 10 includes a control device 15 that controls an operation of a processing such as, for example, substrate transfer, polishing, or cleaning.

The loading/unloading section 12 includes a plurality of front loading units 20, a traveling mechanism 21, and two transfer robots 22. A substrate cassette is placed on the front loading unit 20 to stock a large number of substrates (substrates). The transfer robot 22 includes two upper and lower hands, and by moving on the travel mechanism 21, operates to take out a substrate W from the substrate cassette in the front loading unit 20 and send the substrate W to the polishing section 13 and also operates to return a completely processed substrate from the cleaning section 14 to the substrate cassette.

The polishing section 13 is an area in which polishing (planarization processing) of the substrate is performed, and is provided with a plurality of polishing units 13A to 13D that are arranged along a longitudinal direction of the substrate processing apparatus. Each polishing unit includes a top ring for polishing the substrate W on a polishing table while pressing the substrate W against a polishing pad, a polishing liquid supply nozzle that supplies a polishing liquid or a dressing liquid to the polishing pad, a dresser that performs dressing of a polishing surface of the polishing pad, and an atomizer that sprays a mixed fluid of a liquid and a gas or a misty liquid onto the polishing surface to wash off polishing wastes or abrasive particles remaining on the polishing surface.

Between the polishing section 13 and the cleaning section 14, first and second linear transporters 16 and 17 are provided as a transfer mechanism that transfers the substrate W. The first linear transporter 16 is freely movable between a first position for receiving the substrate W from the loading/unloading section 12, second and third positions for performing exchange of the substrate W with the polishing units 13A and 13B, and a fourth position for delivering the substrate W to the second linear transporter 17.

The second linear transporter 17 is freely movable between a fifth position for receiving the substrate W from the first linear transporter 16 and sixth and seventh positions for performing exchange of the substrate W with the polishing units 13C and 13D. Between the transporters 16 and 17, a swing transporter 23 is provided to deliver the substrate W to the cleaning section 14.

The cleaning section 14 includes a first substrate cleaning device 30, a second substrate cleaning device 31, a substrate drying device 32, and transfer robots 33 and 34 for performing exchange of the substrate between these devices. The substrate W polished by the polishing unit is cleaned (primarily cleaned) by the first substrate cleaning device 30 and then further cleaned (completely cleaned) by the second substrate cleaning device 31. The cleaned substrate is carried into the substrate drying device 32 from the second substrate cleaning device 31 and subjected to spin drying. The dried substrate W is returned to the loading/unloading section 12.

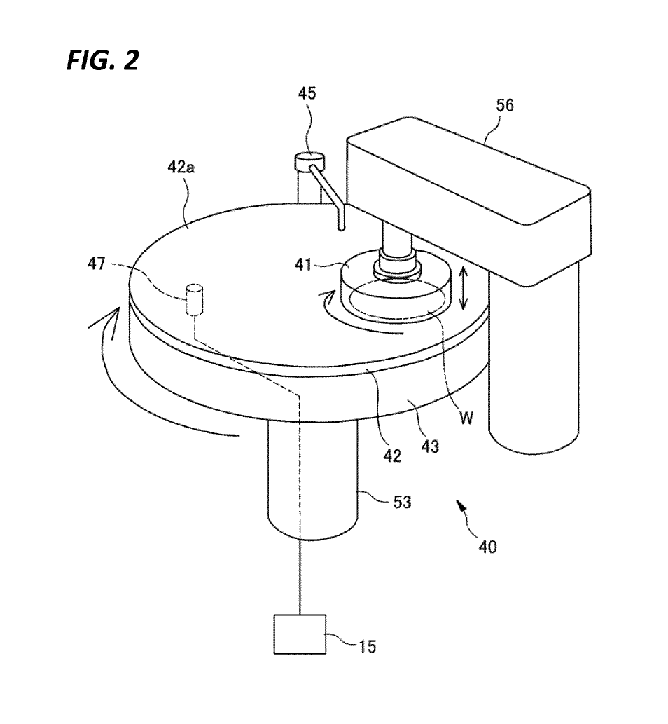

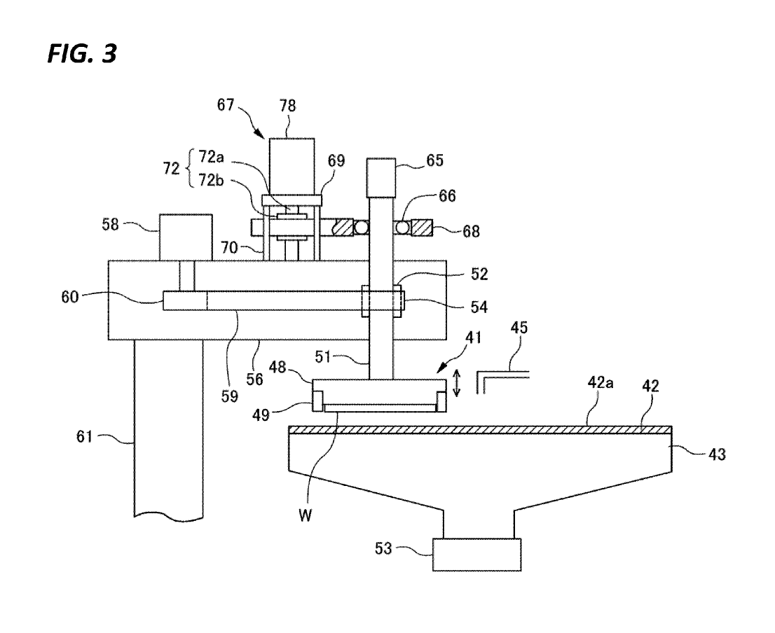

FIG. 2 is a perspective view schematically illustrating a configuration of a polishing unit, and FIG. 3 is a side view schematically illustrating the configuration of the polishing unit. The polishing unit 40 includes a top ring (substrate holding device) 41 that holds and rotates the wafer (substrate) W, a polishing table 43 that supports a polishing pad 42, a polishing liquid supply nozzle 45 that supplies slurry (polishing liquid) to the polishing pad 42, and a film thickness sensor 47 that acquires a signal that changes according to a film thickness of the wafer W.

The top ring 41 is configured to hold the wafer W on the lower surface thereof by vacuum suction. The top ring 41 and the polishing table 43 rotate in a direction indicated by the arrow, and in this state, the top ring 41 presses the wafer W against a polishing surface 42a on the upper side of the polishing pad 42. Under the presence of the polishing liquid supplied from the polishing liquid supply nozzle 45 onto the polishing pad 42, the wafer W is polished by being in sliding contact with the polishing pad 42.

For example, an optical sensor or an eddy current sensor is used as the film thickness sensor 47, and the film thickness sensor 47 is provided inside the polishing table 43. During polishing of the wafer W, the film thickness sensor 47 rotates together with the polishing table 43, and acquires a film thickness signal corresponding to the film thickness when traversing the surface of the wafer W. The film thickness signal from the film thickness sensor 47 may be transmitted to the control device 15, and the control device 15 may estimate the film thickness of the wafer W that is being polished.

In FIG. 3, the top ring 41 includes a top ring body 48 that presses the wafer W against the polishing surface 42a, and a retainer ring 49 that supports the outer peripheral portion of the wafer W to prevent the wafer W from protruding from the top ring 41. The top ring 41 is connected to a top ring shaft 51, and a rotary joint 65 is attached to an upper end of the top ring shaft 51. The top ring shaft 51 is configured to vertically move relative to a head arm 56 by a vertical movement mechanism 67, and moves the entire top ring 41 up and down relative to the head arm 26.

The vertical movement mechanism 67 that vertically moves the top ring shaft 51 and the top ring 41 includes a bridge 68 that rotatably supports the top ring shaft 51 via a bearing 66, a ball screw 72 attached to the bridge 68, a support base 69 supported by columns 70, and a servomotor 78 provided on the support base 69. The support base 69 that supports the servomotor 78 is fixed to the head arm 56 via the columns 70.

The ball screw 72 includes a screw shaft 72a connected to the servomotor 78 and a nut 72b to which the screw shaft 72a is screwed. The bridge 68 is integrated with the top ring shaft 51 so as to vertically move. Thus, when the servomotor 78 is driven, the bridge 68 vertically moves via the ball screw 72, so that the top ring shaft 51 and the top ring 41 vertically move.

The top ring shaft 51 is connected to a rotating cylinder 52 via a key (not illustrated). The rotating cylinder 52 is provided with a timing pulley 54 on the outer peripheral portion thereof. A head motor 58 is fixed to the head arm 56, and the timing pulley 54 is connected to a timing pulley 60 provided on the head motor 58 via a timing belt 59. By rotationally driving the head motor 58, the rotating cylinder 52 and the top ring shaft 51 rotate integrally via the timing pulley 60, the timing belt 59, and the timing pulley 54, so that the top ring 41 rotates. The head arm 56 is supported by an arm shaft 61 that is rotatably supported on a frame (not illustrated). An operation of each component in the apparatus including the head motor 58 and the servomotor 78 constituting the polishing apparatus is controlled by the control device 15.

The head arm 56 is configured to be rotatable about the arm shaft 61, and the top ring 41 holding the wafer W on the lower surface thereof is moved from a position for reception of the wafer W to a polishing position on the upper side of the polishing table 43 by the rotation of the head arm 56. The polishing liquid is supplied from the polishing liquid supply nozzle 45 onto the polishing pad 42 while the top ring 41 and the polishing table 43 rotate respectively. In this state, the top ring 41 is lowered to a predetermined position (height) to press the wafer W against the polishing surface 42a of the polishing pad 42 at a predetermined position, so that the wafer W is brought into sliding contact with the polishing surface 42a so that the surface thereof is polished.

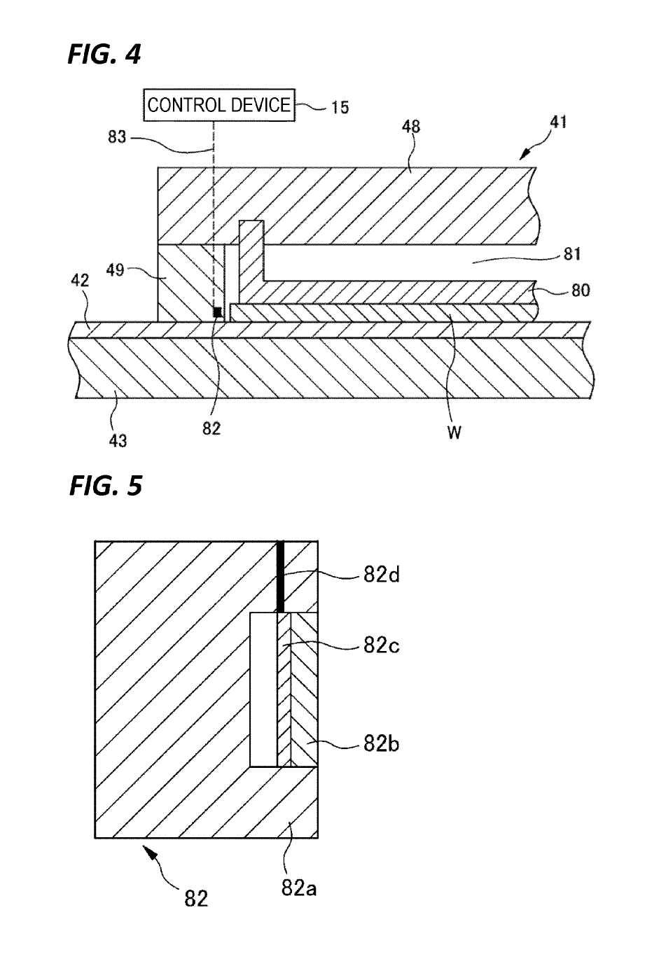

The top ring body 48 and the retainer ring 49 constituting the top ring 41 are configured to rotate integrally by rotation of the top ring shaft 51. In FIG. 4, an elastic membrane 80 is attached to the lower side of the top ring so as to be in contact with the back surface of the wafer W, and the lower surface of the elastic membrane 80 constitutes a substrate holding surface. The elastic membrane 80 includes an annular partition wall extending in the vertical direction, so that a pressure chamber 81 is formed between the elastic membrane 80 and the top ring body 48.

A pressure fluid (gas) is supplied to the pressure chamber 81 from a fluid supply source (not illustrated), and the pressure in the pressure chamber 81 may be adjusted by controlling a valve (not illustrated) to enable formation of a negative pressure in the pressure chamber 81. In addition, the pressure chamber 81 is connected to an atmosphere opening mechanism (not illustrated) for opening the pressure chamber 81 to the atmosphere.

A through hole (not illustrated) is formed in the elastic membrane 80. By forming a negative pressure in the through hole, the wafer W may be held on the substrate holding surface of the elastic membrane 80. The elastic membrane 80 is formed of a rubber material or a synthetic resin having excellent strength and durability such as, for example, ethylene propylene rubber (EPDM), polyurethane rubber, or silicone rubber.

The retainer ring 49 is disposed so as to surround the top ring body 48 and the elastic membrane 80. The retainer ring 49 is a member formed of a ring-shaped resin material that comes into contact with the polishing surface 42a of the polishing pad 42. The retainer ring 49 is disposed so as to surround the outer periphery of the wafer W held on the top ring body 48, and supports the outer periphery of the wafer W to prevent the wafer W that is being polished from protruding from the top ring 41.

An annular retainer ring pressing mechanism (not illustrated) is connected to the upper surface of the retainer ring 49, and applies a uniform downward load to the entire upper surface of the retainer ring 49. Therefore, the annular retainer ring pressing mechanism presses the lower surface of the retainer ring 49 against the polishing surface of the polishing pad 42.

As illustrated in FIG. 4, a deflection detection device 82 as a sensor member is embedded in the retainer ring 49. As will be described later, the deflection detection device 82 includes a pressure sensor that outputs a pressure signal corresponding to the amount of deflection of the retainer ring pressed by the wafer W that is being polished. The deflection detection device 82 is connected to the control device 15 via a signal line 83, and outputs the detected pressure signal to the control device 15.

In an example of FIG. 4, the deflection detection device 82 is disposed in the vicinity of the wafer W that is being polished (i.e., at a position at which the deflection detection device faces the wafer W) inside the retainer ring 49, and thus is capable of directly detecting a pressure force from the wafer W that is being polished.

In order to allow the wafer W that is being polished to enter a detection region of the deflection detection device 82, a height position of the deflection detection device 82 (the center position of the deflection detection device 82 from the bottom surface of the retainer ring 49) is determined in consideration of the sum of the thickness center position of the wafer W and the pad sunk amount of the retainer ring 49 with respect to the wafer W. In addition, the sunk amount of the polishing pad 42 is a parameter determined by the pressing force at the time of polishing and the hardness of the polishing pad 42.

For example, when the thickness of the wafer W is 775 μm and the sunk amount of the retainer ring 49 with respect to the wafer W ranges from 10 μm to 100 μm, the height position of the deflection detection device 82 is set to fall within the range from 775÷2+10 μm to 775÷2+100 μm, so that the wafer W that is being polished enters the detection region of the deflection detection device 82. Actually, since the lower surface of the retainer ring 49 is scraped off as polishing proceeds, the detection region of the deflection detection device 82 is further designed in consideration of the amount of abrasion of the retainer ring 49.

In addition, the deflection detection device 82 needs not to be completely embedded in the retainer ring 49, and may be exposed from the inner peripheral surface of the retainer ring 49 as long as it does not affect the polishing profile of the wafer W.

FIG. 5 schematically illustrates a structure of the deflection detection device 82. The deflection detection device 82 includes a support member 82a, a pressing target portion (deflection portion) 82b, a pressure detection portion (deflection detection portion) 82c, and an output wire 82d. The support member 82a is formed of the same material as the retainer ring 49, for example, and supports the pressing target portion 82b, the pressure detection portion 82c, and the output wire 82d therein. As such, the deflection detection device has a structure in which the pressing target portion 82b, the pressure detection portion 82c, and the output wire 82d are embedded inside the deflection detection device 82.

The pressing target portion 82b is formed of the same material as the retainer ring 49 (or a resin material having the same elasticity as that of the retainer ring 49), and deforms upon receiving the pressing force from the wafer W that is being polished to transmit the pressing force to the pressure detection portion 82c. The pressure detection portion 82c generates an electric signal (pressure signal) depending on the pressing force from the wafer W transmitted via the pressing target portion 82b, and uses, for example, a strain gauge or a piezoelectric thin film. The output wire 82d is a metal wire for outputting the pressure signal generated by the pressure detection portion 82c to the outside.

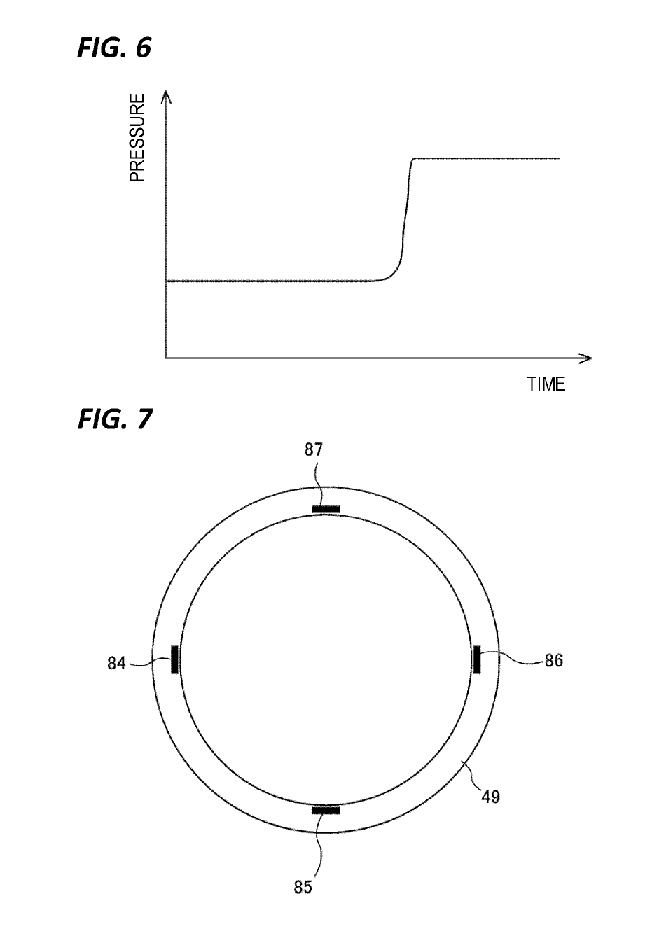

FIG. 6 illustrates an exemplary output signal from the pressure detection portion 82c during a polishing processing of the wafer W. When the film type or structure of a polishing target layer changes during polishing of the wafer W, a frictional resistance that the wafer W receives from the polishing table changes, and accordingly, the pressing force with which the wafer W presses the retainer ring (the pressing target portion 82b) rapidly changes. When the amount of the change deviates from a predetermined range, the end of polishing of the wafer W may be detected. Since the effect of an individual difference or noise of a mechanism such as, for example, a motor or a bearing is prevented as compared with a conventional method of detecting the end of polishing by a change in the torque of a table motor that drives the polishing table 43, the timing of the end of polishing of the wafer W may be accurately detected.

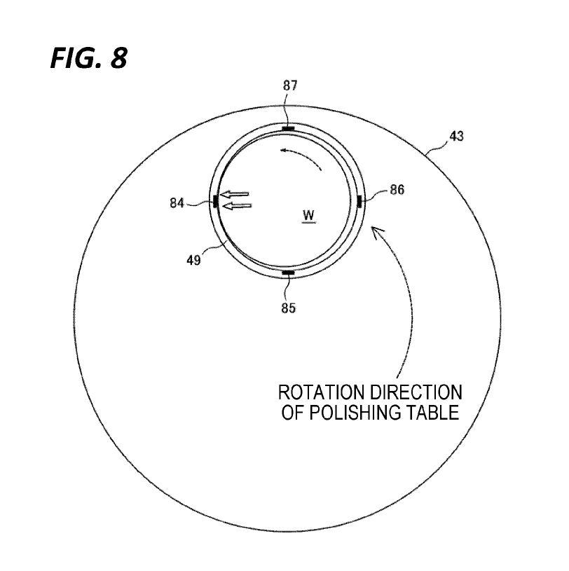

In the present embodiment, the retainer ring 49 is approximately equidistantly provided with a plurality of deflection detection devices 82 described above. FIG. 7 illustrates an example thereof, and in this example, four deflection detection devices 84 to 87 are arranged. As illustrated in FIG. 8, a gap is formed between the wafer W and the retainer ring 49, and due to a frictional force between the wafer W and the retainer ring 49 caused by rotation of the polishing table 43, the wafer W moves toward one side of the retainer rings 49 relative thereto (in an example of FIG. 8, a large gap is illustrated from the viewpoint of easy viewing, but the gap is small in an actual apparatus). In addition, the wafer W that is being polished rotates together with the top ring. Therefore, the pressing force with which the wafer W that is being polished presses the retainer ring 49 is not consistent over the entire inner peripheral surface of the retainer ring 49, and a change (distribution) in the pressing force occurs depending on a position.

Thus, in the polishing apparatus of the present embodiment, by using information on the pressing force from the wafer W detected by each of the four deflection detection devices 84 to 87, the control device 15 extracts data on the pressing force from the wafer W. For example, one having the maximum value among the pressing forces detected from the four deflection detection devices 84 to 87 may be extracted, or a value obtained by averaging a plurality of data on pressing forces having high numerical values may be extracted as the pressing force from the wafer W. Moreover, when the amount of change in the pressing force detected from all of the deflection detection devices deviates from a predetermined range, this may be determined as the end of polishing.

In addition, the number and arrangement of deflection detection devices are not limited to those illustrated in FIG. 8, and one to three deflection detection devices may be arranged, or five or more deflection detection devices may be arranged. The number of deflection detection devices may be determined according to the polishing rate and the rotational speed of the top ring. For example, when the polishing rate is low and the rotational speed of the top ring is high, the number of deflection detection devices may be reduced.

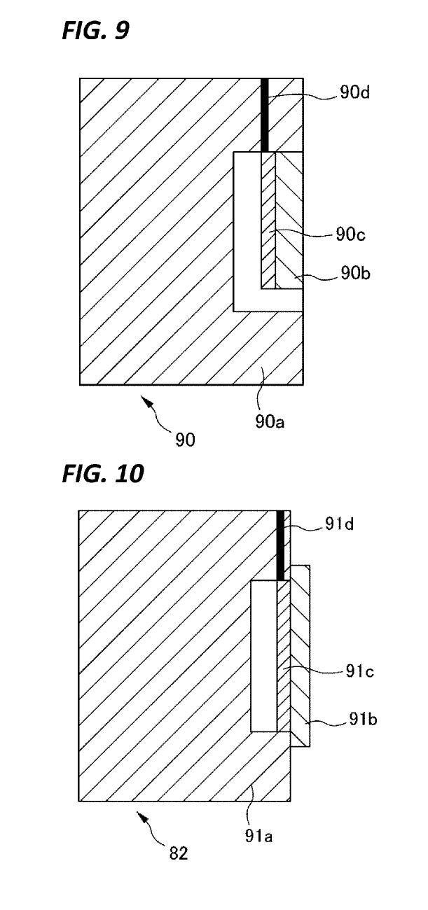

In addition, the configuration of the deflection detection device is not limited to the structure illustrated in FIG. 5, and various structures may be adopted as long as they are capable of detecting the pressing force received by the retainer ring 49. FIGS. 9 to 12 illustrate other embodiments of the deflection detection device.

In an example illustrated in FIG. 9, a deflection detection device 90 includes a pressing target portion (deflection portion) 90b, a pressure detection portion (deflection detecting portion) 90c, an output wire 90d, and a support member 90a that supports these. Since each of the pressing target portion 90b and the pressure detection portion 90c is fixed only at one side surface thereof to the support member 90a, the deflection detection device 90 is a so-called one-sided supporting cantilever type pressure sensor. Since the cantilever type pressure sensor is supported only at one side, it has a detection region different from that of a diaphragm type pressure detection device (e.g., the example of FIG. 5). The height position (the height from the bottom surface of the retainer ring 49) of the most deflected portion of the pressing target portion 90b is set to the sum of the thickness center of the wafer and the pad sunk amount of the retainer ring with respect to the wafer.

In an example illustrated in FIG. 10, a deflection detection device 91 includes a pressing target portion (deflection portion) 91b, a pressure detection portion (deflection detection portion) 91c, an output wire 91d, and a support member 91a that supports these. Since the pressing target portion 91b may be attached to the side surface of the support member 91a and the pressing target portion 91b needs only to be attached later, the deflection detection device 91 may be easily manufactured as compared with other types of deflection detection devices. In addition, the respective members constituting the deflection detection devices 90 and 91 illustrated in FIGS. 9 and 10 may be formed of the same material as the deflection detection device 82 in FIG. 5.

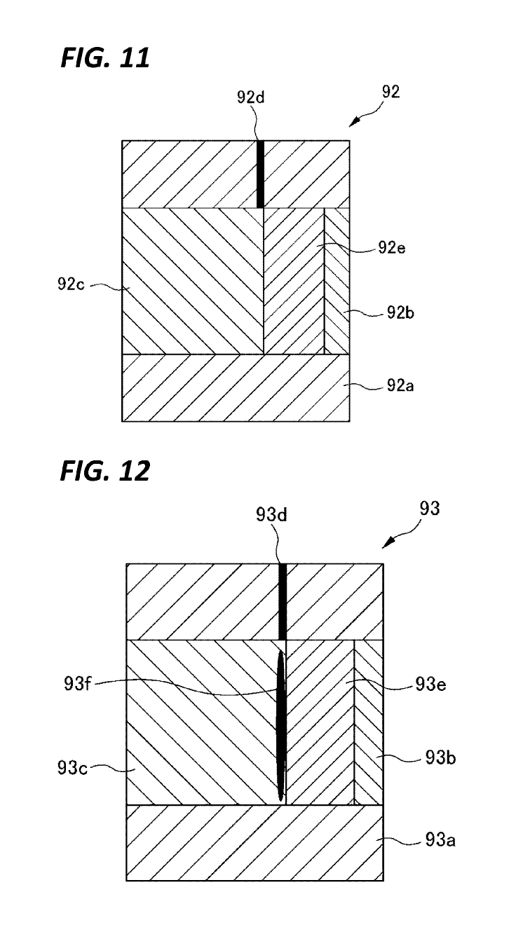

In an example illustrated in FIG. 11, a deflection detection device 92 includes a pressing target portion (deflection portion) 92b, a pressure detection portion (deflection detection portion) 92c, an output wire 92d, a deflection transmission portion 92e, and a support member 92a that supports these. For example, a semiconductor piezoresistive (or capacitive) sensor may be used as the pressure detection portion 92c. In the present embodiment, an example is illustrated in which a change in the pressing force of the wafer is detected by a sensor that directly converts a pressure into an electric signal. However, the present embodiment is not limited as to the type of the sensor, and even when, for example, a load sensor or an acceleration sensor is used, a change in the wafer pressing force may also be similarly grasped. In addition, the deflection transmission portion 92e is not limited as to a material thereof as long as it is capable of transmitting the pressing force that the pressing target portion 92b has received from the wafer W, but the material of the deflection transmission portion 92e may be, for example, a silicone-based adhesive, an epoxy-based adhesive, a UV curing resin, a silicone oil, or a conductive adhesive.

In an example illustrated in FIG. 12, a deflection detection device 93 includes a pressing target portion (deflection portion) 93b, a pressure detection portion (deflection detection portion) 93c, an output wire 93d, and a support member 93a that supports these. In this exemplary embodiment, the pressure detection portion 93c is in contact with a deflection transmission portion 93e in the vicinity of a boundary (a resonance region 93f) with the deflection transmission portion 93e. The internal pressure of the deflection transmission portion 93e rises by the pressing force from the wafer W and the viscosity given to the resonance region 93f that reciprocates at the time of resonance changes, so that the amplitude of vibrations changes, which results in a change in the Q value. Therefore, the pressing force from the wafer W may be detected. However, the pressure detection method is not limited to this example, and for example, a detection method using a change in frequency depending on deflection may be used.

Even with the configurations of the deflection detection devices 90 to 93 illustrated in FIGS. 9 to 12, the pressure detection portion may detect the pressing force transmitted via the pressing target portion from the wafer W that is being polished.

In the above embodiments, one deflection detection device is disposed in each predetermined region (one region or a plurality of regions) of the retainer ring, but the present disclosure is not limited thereto, and a plurality of deflection detection devices may be disposed in each predetermined region.

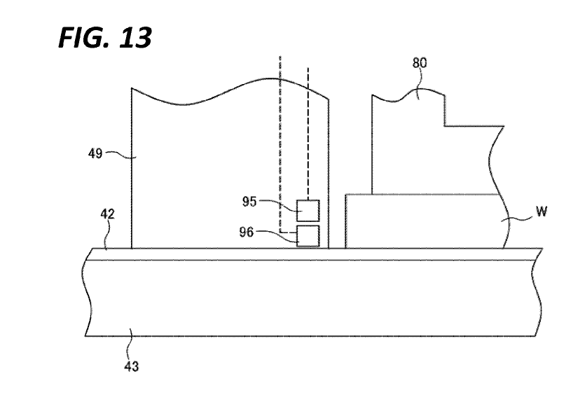

FIG. 13 illustrates an example in which two deflection detection devices 95 and 96 are arranged adjacent to each other. The upper deflection detection device 95 is disposed such that a pressing target portion (deflection portion) faces inward (toward the side of the wafer W that is being polished) similarly to the description in the above embodiments, and outputs a signal corresponding to the pressing force (frictional force) from the wafer W, so that the control device 15 may determine whether or not polishing ends by detecting a change in the pressing force. Here, the end of polishing also includes a determination of whether to end each step when a wafer polishing processing is continued under different polishing conditions for each step.

The lower deflection detection device 96 is disposed such that a pressing target portion (deflection portion) faces the lower side (the polishing pad side), and detects the pressing force received from the polishing pad during a polishing processing. When the retainer ring wears as the polishing processing is repeated, the pressing force that the retainer ring receives from the polishing pad increases. When the pressing force detected by the deflection detection device 96 exceeds a predetermined value, the control device 15 may determine that this is the timing at which the retainer ring needs to be replaced, and may display the intent thereof on a display (not illustrated), for example, so as to urge an operator to replace the retainer ring. In addition, a plurality of deflection detection devices 96 may be provided in the radial direction of the retainer ring. Actually, the amount of wear of the retainer ring may be distributed in the radial direction according to the inclination of the retainer ring. In order to estimate the more accurate lifetime, it is effective to monitor the wear side of the retainer ring in the radial direction.

In the above embodiments, the wire for the output of the pressure signal is provided, but the present disclosure is not limited thereto, and for example, a wireless communication unit for wirelessly transmitting the pressure signal to the control device may be provided in the deflection detection device. In addition, a storage unit (memory) may be provided in the deflection detection device to store information on the part number (part ID), the serial number, the expiration date, the shipping inspection data (rubber physical property inspection data of the elastic membrane, outer size data, and bulging measurement data), manufacturing data (data on processing conditions such as the press pressure, the press temperature, the press time, the secondary vulcanization temperature, and the secondary vulcanization time) of the retainer ring as an expendable item. Prior to the polishing of the wafer W, the control device 15 may read out the information stored in the storage unit of the deflection detection device and set a substrate processing condition (a recipe or a machine constant).

In addition, the control device 15 may acquire information on the type, the replacement timing, and the number of distortion measurement times of the retainer ring, and based on the information, may calculate a date of the maintenance (or time to maintenance) of the substrate processing apparatus and display and output the data. Therefore, the operator may appropriately grasp the maintenance timing of the apparatus.

In addition, the control device may be configured to automatically order an expendable item such as, for example, the retainer ring when the calculated maintenance date approaches (e.g., several days ago). Therefore, it is possible to reliably prepare the expendable item at the time of maintenance. In addition, a program that causes the control device to calculate the maintenance date or to order an expendable item may be stored in advance in the memory of the control device, or may be installed later via, for example, the Internet.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A substrate processing apparatus comprising:
a retainer ring having an annular shape configured to support an outer periphery of a substrate to be polished; and
a first sensor provided inside the retainer ring and configured to detect a pressing force with which the substrate presses the retainer ring during a polishing process of the substrate.

2. A substrate processing apparatus comprising:
a retainer ring having an annular shape configured to support an outer periphery of a substrate to be polished;
a first sensor provided inside the retainer ring and configured to detect a pressing force with which the substrate presses the retainer ring during a polishing process of the substrate; and
a controller configured to determine that the polishing process performed on the substrate has ended when an amount of change in a pressing force detected by the first sensor deviates from a predetermined range.

3. The substrate processing apparatus of claim 2, wherein the first sensor is a deflection detector including:
a pressing target that undergoes a deflection by being pressed by the substrate during the polishing process;
a pressure detector disposed adjacent to the pressing target and configured to detect an amount of deflection of the pressing target as the pressing force; and
a support configured to support the pressing target and the pressure detector.

4. The substrate processing apparatus of claim 3, wherein one end of the pressing target is not supported by the support.

5. The substrate processing apparatus of claim 3, wherein the pressing target and the pressure detector are embedded in the support.

6. The substrate processing apparatus of claim 3, wherein the pressure detector is embedded in the support, and the pressing target is attached to an outer surface of the support.

7. The substrate processing apparatus of claim 3, further comprising:
a pressure transmitter disposed between the pressing target and the pressure detector and configured to transmit the pressing force that the pressing target has received from the substrate, to the pressure detector.

8. The substrate processing apparatus of claim 3, wherein a plurality of deflection detectors is disposed at a plurality of positions in the retainer ring, and the controller performs the determination based on information on the pressing force from the plurality of deflection detector.

9. The substrate processing apparatus of claim 2, further comprising:
a second sensor provided in a vicinity of the first sensor inside the retainer ring and configured to detect a pressing force from a polishing pad that polishes the substrate,
wherein the controller determines whether or not to replace the retainer ring based on an amount of change in the pressing force detected from the second sensor.
